(19) United States
(12) Patent Application Publication
(10) Pub. No.: US 2024/0025007 A1
(43) Pub. Date: Jan. 25, 2024

(54) POLISHING METHOD AND POLISHING APPARATUS

(71) Applicant: EBARA CORPORATION, Tokyo (JP)

(72) Inventor: Osamu NABEYA, Tokyo (JP)

(21) Appl. No.: 18/223,326

(22) Filed: Jul. 18, 2023

(30) Foreign Application Priority Data
Jul. 25, 2022 (JP) 2022-117791

(51) Int. Cl. B24B 37/04; B24B 37/005

(52) U.S. Cl. CPC B24B 37/042; B24B 37/005

(57) ABSTRACT

A polishing method for a wafer using a polishing head having a plurality of pressure chambers formed by an elastic membrane is disclosed. The polishing method includes: forming a positive pressure in a first pressure chamber and forming a negative pressure in a second chamber to move fluid present between an upper surface of the wafer and the first pressure chamber outward; then forming a positive pressure in the second chamber and forming a negative pressure in a third pressure chamber to move the fluid present between the upper surface of the wafer and the second pressure chamber outward; then forming a positive pressure in outermost pressure chamber of the plurality of pressure chambers to move the fluid present between the upper surface of the wafer and the outermost pressure chamber outward to thereby cause the fluid to flow out from the upper surface of the wafer; and then pressing a lower surface of the wafer against a polishing surface with the elastic membrane to polish the lower surface of the wafer.

### CROSS REFERENCE TO RELATED APPLICATION

This document claims priority to Japanese Patent Application No. 2022-117791 filed Jul. 25, 2022, the entire contents of which are hereby incorporated by reference.

### BACKGROUND

Chemical mechanical polishing (CMP) is a technique of polishing a surface of a wafer by pressing the wafer against a polishing surface while supplying a polishing liquid onto the polishing surface to place the wafer in sliding contact with the polishing surface in the presence of the polishing liquid. During polishing of the wafer, the wafer is pressed against the polishing surface by a polishing head. The surface of the wafer is planarized by a chemical action of the polishing liquid and mechanical action(s) of abrasive grains contained in the polishing liquid and/or a polishing pad.

FIG. 12 is a cross-sectional view schematically showing a polishing head 100. The polishing head 100 has an elastic membrane 110 being in contact with an upper surface of a wafer W1. This elastic membrane 110 has a shape that forms a plurality of pressure chambers 101 to 104, and a pressure in each of the pressure chambers 101 to 104 can be regulated independently. Therefore, the polishing head 100 can press a plurality of regions of the wafer W1 corresponding to these pressure chambers 101 to 104 with different forces, and can achieve a desired film-thickness profile of the wafer W1.

After polishing of the wafer W1 is terminated, the polished wafer W1 is transferred to a next process by a transfer device. As shown in FIG. 13, a next wafer W2 is moved to a transfer position below the polishing head 100 by the transfer device. At the same time, the polishing head 100 is cleaned with a liquid (e.g., pure water) supplied from a cleaning nozzle 115, so that a polishing liquid and polishing debris are removed from the polishing head 100. The next wafer W2 is then held by the polishing head 100 and is transferred to a position above a polishing surface by the polishing head 100. The wafer W2 is pressed against the polishing surface by the polishing head 100 and polished in the presence of the polishing liquid.

However, as shown in FIG. 14, fluid Q, such as the liquid having been used for cleaning of the polishing head 100, or air, may be present between an upper surface of the wafer W2 and the elastic membrane 110 of the polishing head 100. The presence of the fluid Q between the upper surface of the wafer W2 and the polishing head 100 may prevent the polishing head 100 from appropriately applying the forces to the plurality of regions of the wafer W2 corresponding to the pressure chambers 101 to 104. For example, if the fluid Q spreads over some pressure chambers, a pressure in an adjacent pressure chamber is transmitted to the fluid Q, and as a result, an unintended force may be applied to the wafer W2. In the example shown in FIG. 14, although a pressure in a central pressure chamber 101 is lowered in order to reduce a polishing rate in a central region of the wafer W2, a pressure in an adjacent pressure chamber 102 is applied to the central region of the wafer W2 via the fluid Q. As a result, the polishing rate of the central region of the wafer W2 cannot be lowered. Thus, the fluid Q present between the wafer W2 and the polishing head 100 may prevent the polishing head 100 from applying an appropriate force to the wafer W2.

### SUMMARY

There are provided a polishing method and a polishing apparatus that can force fluid to flow out from an upper surface of a wafer and enable a polishing head to apply an appropriate force to the wafer.

Embodiments, which will be described below, relate to a technique for causing a fluid to flow out from an upper surface of a wafer and polishing the wafer.

In an embodiment, there is provided a polishing method for a wafer using a polishing head having a plurality of pressure chambers formed by an elastic membrane, comprising: forming a positive pressure in a first pressure chamber and forming a negative pressure in a second chamber to move fluid present between an upper surface of the wafer and the first pressure chamber outward, the plurality of pressure chambers including the first pressure chamber and the second pressure chamber located outwardly of the first pressure chamber; then forming a positive pressure in the second chamber and forming a negative pressure in a third pressure chamber to move the fluid present between the upper surface of the wafer and the second pressure chamber outward, the plurality of pressure chambers further including the third pressure chamber located outwardly of the second pressure chamber; then forming a positive pressure in outermost pressure chamber of the plurality of pressure chambers to move the fluid present between the upper surface of the wafer and the outermost pressure chamber outward to thereby cause the fluid to flow out from the upper surface of the wafer; and then pressing a lower surface of the wafer against a polishing surface with the elastic membrane to polish the lower surface of the wafer.

In an embodiment, a timing to start forming the positive pressure in the first pressure chamber is the same as a timing to start forming the negative pressure in the second pressure chamber, and a timing to start forming the positive pressure in the second pressure chamber is the same as a timing to start forming the negative pressure in the third pressure chamber.

In an embodiment, forming the negative pressure in the second pressure chamber includes lowering a pressure in the second pressure chamber to a negative-pressure set value, and then establishing a fluid communication between the second pressure chamber and the atmosphere, and forming the negative pressure in the third pressure chamber includes lowering a pressure in the third pressure chamber to a negative-pressure set value, and then establishing a fluid communication between the third pressure chamber and the atmosphere.

In an embodiment, a timing to start forming the negative pressure in the second pressure chamber is prior to a timing to start forming the positive pressure in the first pressure chamber, and a timing to start forming the negative pressure in the third pressure chamber is prior to a timing to start forming the positive pressure in the second pressure chamber.

In an embodiment, forming the negative pressure in the second pressure chamber includes lowering a pressure in the second pressure chamber to a negative-pressure set value, and then releasing the negative pressure in the second pressure chamber, forming the positive pressure in the first pressure chamber is performed during releasing of the negative pressure in the second pressure chamber, forming the negative pressure in the third pressure chamber includes lowering a pressure in the third pressure chamber to a negative-pressure set value, and then releasing the negative pressure in the third pressure chamber, and forming the positive pressure in the second pressure chamber is performed during releasing of the negative pressure in the third pressure chamber.

In an embodiment, the first pressure chamber is located at a central portion of the elastic membrane.

In an embodiment, forming the positive pressure in the first pressure chamber includes increasing a pressure in the first pressure chamber to a first positive-pressure set value, and then maintaining the pressure in the first pressure chamber at the first positive-pressure set value, and forming the positive pressure in the second pressure chamber includes increasing a pressure in the second pressure chamber to a second positive-pressure set value, and then maintaining the pressure in the second pressure chamber at the second positive-pressure set value.

In an embodiment, there is provided a polishing apparatus for polishing a wafer, comprising: a polishing head having a plurality of pressure chambers formed by an elastic membrane, the polishing head being configured to press the wafer against a polishing surface with the plurality of pressure chambers, the plurality of pressure chambers including a first pressure chamber, a second pressure chamber located outwardly of the first pressure chamber, and a third pressure chamber located outwardly of the second pressure chamber; and an operation controller configured to control an operation of the polishing apparatus, the operation controller being configured to instruct the polishing apparatus to: form a positive pressure in the first pressure chamber and form a negative pressure in the second chamber to move fluid present between an upper surface of the wafer and the first pressure chamber outward; form a positive pressure in the second chamber and form a negative pressure in the third pressure chamber to move the fluid present between the upper surface of the wafer and the second pressure chamber outward; form a positive pressure in outermost pressure chamber of the plurality of pressure chambers to move the fluid present between the upper surface of the wafer and the outermost pressure chamber outward to thereby cause the fluid to flow out from the upper surface of the wafer; and then press a lower surface of the wafer against the polishing surface with the elastic membrane to polish the lower surface of the wafer.

In an embodiment, the operation controller is configured to: operate the polishing apparatus such that a timing to start forming the positive pressure in the first pressure chamber is the same as a timing to start forming the negative pressure in the second pressure chamber; and operate the polishing apparatus such that a timing to start forming the positive pressure in the second pressure chamber is the same as a timing to start forming the negative pressure in the third pressure chamber.

In an embodiment, the operation controller is configured to: operate the polishing apparatus such that forming the negative pressure in the second pressure chamber includes lowering a pressure in the second pressure chamber to a negative-pressure set value, and then establishing a fluid communication between the second pressure chamber and the atmosphere; and operate the polishing apparatus such that forming the negative pressure in the third pressure chamber includes lowering a pressure in the third pressure chamber to a negative-pressure set value, and then establishing a fluid communication between the third pressure chamber and the atmosphere.

In an embodiment, the operation controller is configured to: operate the polishing apparatus such that a timing to start forming the negative pressure in the second pressure chamber is prior to a timing to start forming the positive pressure in the first pressure chamber; and operate the polishing apparatus such that a timing to start forming the negative pressure in the third pressure chamber is prior to a timing to start forming the positive pressure in the second pressure chamber.

In an embodiment, the operation controller is configured to: operate the polishing apparatus such that forming the negative pressure in the second pressure chamber includes lowering a pressure in the second pressure chamber to a negative-pressure set value, and then releasing the negative pressure in the second pressure chamber, forming the positive pressure in the first pressure chamber being performed during releasing of the negative pressure in the second pressure chamber; and operate the polishing apparatus such that forming the negative pressure in the third pressure chamber includes lowering a pressure in the third pressure chamber to a negative-pressure set value, and then releasing the negative pressure in the third pressure chamber, forming the positive pressure in the second pressure chamber being performed during releasing of the negative pressure in the third pressure chamber.

In an embodiment, the first pressure chamber is located at a central portion of the elastic membrane.

In an embodiment, the operation controller is configured to: operate the polishing apparatus such that forming the positive pressure in the first pressure chamber includes increasing a pressure in the first pressure chamber to a first positive-pressure set value, and then maintaining the pressure in the first pressure chamber at the first positive-pressure set value; and operate the polishing apparatus such that forming the positive pressure in the second pressure chamber includes increasing a pressure in the second pressure chamber to a second positive-pressure set value, and then maintaining the pressure in the second pressure chamber at the second positive-pressure set value.

According to the above-described embodiments, the fluid present on the upper surface of the wafer is forced to move outward by forming a positive pressure in an inner pressure chamber of adjacent pressure chambers, and forming a negative pressure in an outer pressure chamber of the adjacent pressure chambers. The fluid present on the upper surface of the wafer is moved outward by sequentially performing this operation in pressure chambers adjacent outwardly. Furthermore, the fluid can flow out from the upper surface of the wafer by forming the positive pressure in the outermost pressure chamber. As a result, the elastic membrane forming the pressure chambers can apply an intended force against the wafer.

### BRIEF DESCRIPTION OF THE DRAWINGS

FIG. 1 is a schematic diagram showing an embodiment of a polishing apparatus;

FIG. 2 is a cross-sectional view showing an embodiment of a polishing head;

FIG. 3 is a plan view of a transfer device configured to transfer a wafer to the polishing head shown in FIG. 1;

FIG. 4 is a schematic diagram illustrating fluid present on an upper surface of the wafer;

FIG. 5 is a schematic diagram illustrating an elastic membrane of the polishing head when forcing the fluid on the upper surface of the wafer to move outward;

FIG. 6 is a schematic diagram illustrating the elastic membrane of the polishing head when forcing the fluid on the upper surface of the wafer to further move outward;

FIG. 7 is a schematic diagram illustrating the elastic membrane of the polishing head when forcing the fluid on the upper surface of the wafer to further move outward;

FIG. 8 is a schematic diagram illustrating the elastic membrane of the polishing head when forcing the fluid on the upper surface of the wafer to flow out from the wafer;

FIG. 9 is a graph showing a relationship between pressure in a plurality of pressure chamber and time;

FIG. 10 is a graph showing a relationship between pressure in the plurality of pressure chamber and time according to another embodiment of a method of causing the fluid to flow out from the upper surface of the wafer;

FIG. 11 is a graph showing a relationship between pressure in the plurality of pressure chamber and time according still another embodiment of a method of causing the fluid to flow out from the upper surface of the wafer;

FIG. 12 is a cross-sectional view schematically showing a polishing head;

FIG. 13 is a diagram illustrating the polishing head when being cleaned; and

FIG. 14 is diagram illustrating a problem caused by fluid present between an upper surface of a wafer and an elastic membrane of the polishing head.

### DESCRIPTION OF EMBODIMENTS

Embodiments will now be described with reference to the drawings.

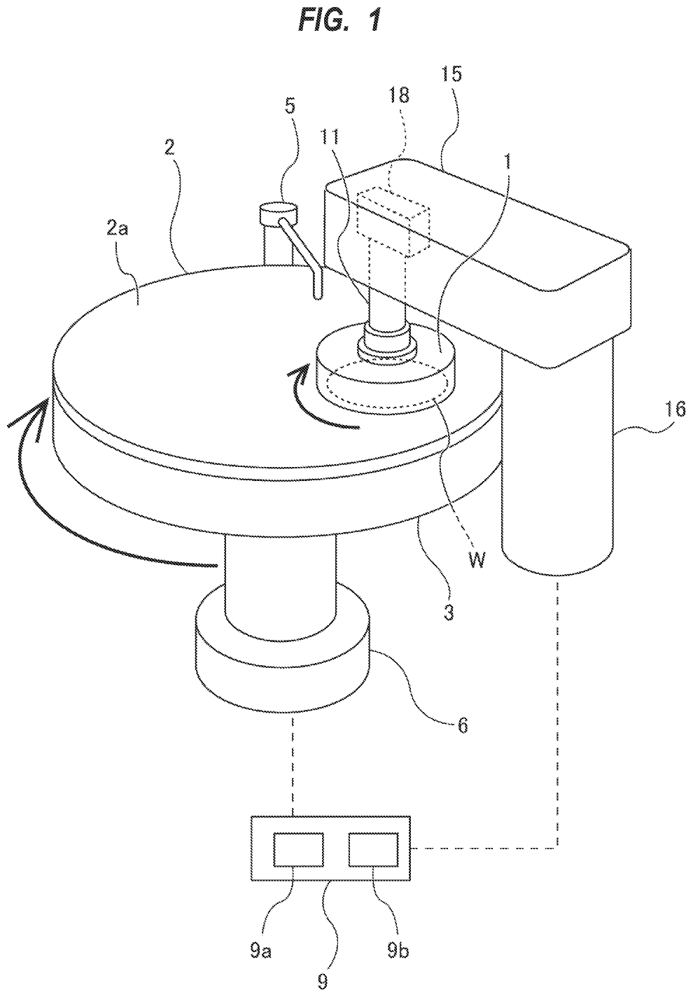

FIG. 1 is a schematic diagram showing an embodiment of a polishing apparatus. As shown in FIG. 1, the polishing apparatus includes a polishing table 3 configured to support a polishing pad 2, a polishing head 1 configured to press a wafer W, which is an example of a workpiece, against the polishing pad 2, a table motor 6 configured to rotate the polishing table 3, and a polishing-liquid supply nozzle 5 configured to supply a polishing liquid (e.g., slurry containing abrasive grains) onto the polishing pad 2. The polishing pad 2 has a surface constituting a polishing surface 2a for polishing the wafer W.

The polishing table 3 is coupled to the table motor 6, and is configured to rotate the polishing table 3 and the polishing pad 2 together. The polishing head 1 is fixed to an end of a polishing-head shaft 11, and the polishing-head shaft 11 is rotatably supported by a head arm 15. The head arm 15 is rotatably supported by a support shaft 16. The polishing-head shaft 11 is coupled to a vertically moving mechanism 18 disposed in the head arm 15. The vertically moving mechanism 18 is configured to vertically move the polishing-head shaft 11 in its axial direction. The vertical movement of the polishing-head shaft 11 caused by the vertically moving mechanism 18 allows the wafer W held by the polishing head 1 to move close to and away from the polishing pad 2 on the polishing table 3.

The polishing apparatus further includes an operation controller 9 configured to control operations of each component of the polishing apparatus. The operation controller 9 is electrically connected to the polishing head 1, the polishing table 3, the polishing-liquid supply nozzle 5, and the vertically moving mechanism 18, and controls operations of the polishing head 1, the polishing table 3, the polishing-liquid supply nozzle 5, and the vertical moving mechanism 18. The operation controller 9 includes a memory 9a storing programs, and an arithmetic device 9b configured to perform arithmetic operations according to instructions contained in the programs. The operation controller 9 is composed of at least one computer. The memory 9a includes a main memory, such as a random-access memory (RAM), and an auxiliary memory, such as a hard disk drive (HDD) or a solid state drive (SSD). Examples of the arithmetic device 9b include a CPU (central processing unit) and a GPU (graphic processing unit). However, the specific configuration of the operation controller 9 is not limited to these examples.

Polishing of the wafer W is performed as follows. The operation controller 9 instructs the polishing table 3, the polishing head 1, and the polishing-liquid supply nozzle 5 to supply the polishing liquid onto the polishing surface 2a of the polishing pad 2 on the polishing table 3 from the polishing-liquid supply nozzle 5, while the polishing table 3 and the polishing head 1 are rotating in directions indicated by arrows in FIG. 1. The wafer W is pressed against the polishing surface 2a of the polishing pad 2 by the polishing head 1 in the presence of the polishing liquid between the polishing pad 2 and the wafer W, while the wafer W is being rotated by the polishing head 1. The surface of the wafer W is polished by a chemical action of the polishing liquid and mechanical action(s) of abrasive grains contained in the polishing liquid and/or the polishing pad.

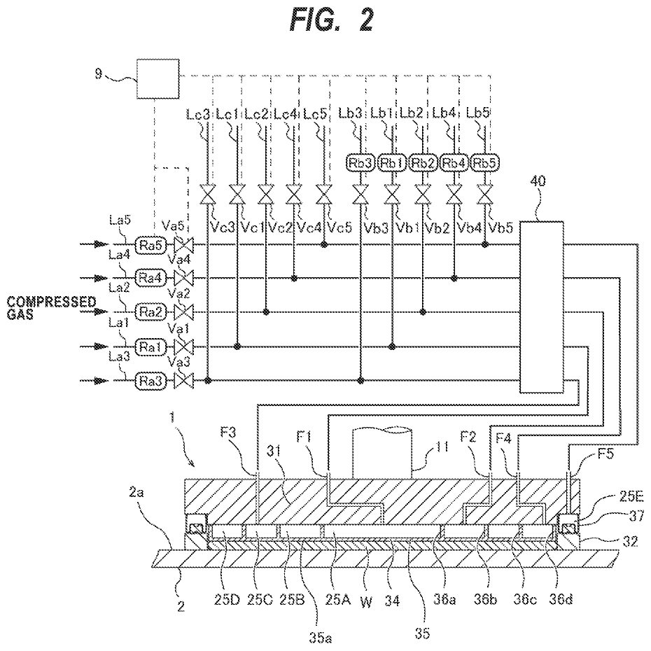

Next, the polishing head 1 will be described. FIG. 2 is a cross-sectional view showing an embodiment of the polishing head 1. The polishing head 1 includes a carrier 31 fixed to the end of the polishing-head shaft 11, an elastic membrane 34 attached to a lower portion of the carrier 31, and a retainer ring 32 arranged below the carrier 31. The retainer ring 32 is arranged around the elastic membrane 34. The retainer ring 32 is an annular structure configured to retain the wafer W so as to prevent the wafer W from being ejected from the polishing head 1 during polishing of the wafer W.

The elastic membrane 34 includes a contact portion 35 having a contact surface 35a which is contactable with an upper surface of the wafer W, and inner wall portions 36a, 36b, 36c and an outer wall portion 36d coupled to the contact portion 35. The contact portion 35 has substantially the same size and the same shape as those of the upper surface of the wafer W. The inner wall portions 36a, 36b, and 36c and the outer wall portion 36d are endless walls concentrically arranged. The outer wall portion 36d is located outwardly of the inner wall portions 36a, 36b, and 36c, and is arranged so as to surround the inner wall portions 36a, 36b, and 36c. In this embodiment, three inner wall portions 36a, 36b, and 36c are provided, while the invention is not limited to this embodiment. In one embodiment, two inner wall portions may be provided, or four or more inner wall portions may be provided.

A plurality of pressure chambers (in this embodiment, four pressure chambers) 25A, 25B, 25C, and 25D are provided between the elastic membrane 34 and the carrier 31. The pressure chambers 25A, 25B, 25C and 25D are formed by the contact portion 35, the inner wall portions 36a, 36b, and 36c, and the outer wall portion 36d of the elastic membrane 34. Specifically, the pressure chamber 25A is located inwardly of the inner wall portion 36a, the pressure chamber 25B is located between the inner wall portion 36a and the inner wall portion 36b, the pressure chamber 25C is located between the inner wall portion 36b and the inner wall portion 36c, and the pressure chamber 25D is located between the inner wall portion 36c and the outer wall portion 36d. Sizes of the pressure chambers 25A, 25B, 25C, and 25D, i.e., distances from the center of the elastic membrane 34 to the inner wall portions 36a, 36b, 36c, and the outer wall 36d are not particularly limited. For example, the inner wall portions 36a, 36b, and 36c and the outer wall portion 36d may be arranged at equal intervals from the center of the elastic membrane 34, or may be arranged at different intervals.

The pressure chamber 25A located in the center of the elastic membrane 34 has a circular shape, while the other pressure chambers 25B, 25C, and 25D have annular shapes. These pressure chambers 25A, 25B, 25C, and 25D are concentrically arranged. The pressure chamber 25B is located outwardly of the pressure chamber 25A, the pressure chamber 25C is located outwardly of the pressure chamber 25B, and the pressure chamber 25D is located outwardly of the pressure chamber 25C. In this embodiment, the elastic membrane 34 forms four pressure chambers 25A to 25D, while in one embodiment, the elastic membrane 34 may form three pressure chambers, or five or more pressure chambers.

An annular membrane (rolling diaphragm) 37 is arranged between the carrier 31 and the retainer ring 32. A pressure chamber 25E is formed inside the membrane 37. Gas delivery lines F1, F2, F3, F4, and F5 are coupled to the pressure chambers 25A, 25B, 25C, 25D, and 25E, respectively. The gas delivery lines F1, F2, F3, F4 and F5 extend through a rotary joint 40 attached to the polishing-head shaft 11.

The gas delivery lines F1, F2, F3, F4, and F5 are coupled togas supply lines La1, La2, La3, La4, and La5, respectively, at locations upstream of the rotary joint 40. The gas supply lines La1, La2, La3, La4, and La5 are coupled to a compressed-gas supply source (not shown) which is a utility supply source provided in a factory where the polishing apparatus is installed. Compressed gas, such as compressed air, is supplied to the pressure chambers 25A, 25B, 25C, 25D, and 25E from the gas supply lines La1, La2, La3, La4, and La5 through the gas delivery lines F1, F2, F3, F4, and F5, respectively.

Gas supply valves Va1, Va2, Va3, Va4, and Va5 and pressure regulators Ra1, Ra2, Ra3, Ra4, and Ra5 are attached to the gas supply lines La1, La2, La3, La4, and La5, respectively. The gas supply valves Va1, Va2, Va3, Va4, and Va5 are, for example, actuator-driven valves, such as solenoid valves, electric valves, or air-operated valves. In one embodiment, gas supply valves Va1 to Va5 may be manually operable. When the gas supply valves Va1 to Va5 are opened, the compressed gas from the compressed-gas supply source is independently supplied into the pressure chambers 25A to 25E through the pressure regulators Ra1 to Ra5. The pressure regulators Ra1 to Ra5 are configured to regulate pressures of the compressed gas in the pressure chambers 25A to 25E.

The gas supply valves Va1 to Va5 and the pressure regulators Ra1 to Ra5 are coupled to the operation controller 9. Operations of the gas supply valves Va1 to Va5 and the pressure regulators Ra1 to Ra5 are controlled by the operation controller 9. The operation controller 9 transmits individual target pressure values of the pressure chambers 25A to 25E to the corresponding pressure regulators Ra1 to Ra5, and the pressure regulators Ra1 to Ra5 operate so as to maintain the pressures in the pressure chambers 25A to 25E at the corresponding target pressure values.

The pressure regulators Ra1 to Ra5 can change the internal pressures of the pressure chambers 25A to 25E independently of each other. Therefore, the polishing head 1 can independently regulate polishing pressures on four corresponding regions of the wafer W (i.e., a central portion, an inner intermediate portion, an outer intermediate portion, and an edge portion) and a pressing force of the retainer ring 32 against the polishing surface 2a of the polishing pad 2. For example, the polishing head 1 can press different regions of the surface of the wafer W against the polishing surface 2a of the polishing pad 2 with different polishing pressures. Therefore, the polishing head 1 can control a film-thickness profile of the wafer W to achieve a target film-thickness profile.

The gas delivery lines F1, F2, F3, F4, and F5 are coupled to vacuum lines Lb1, Lb2, Lb3, Lb4, and Lb5, respectively, at locations upstream of the rotary joint 40. The compressed gas, such as compressed air, is supplied to the pressure chambers 25A, 25B, 25C, 25D, and 25E from the gas supply lines La1, La2, La3, La4, and La5 through the gas delivery lines F1, F2, F3, F4, and F5, respectively. Vacuum valves Vb1, Vb2, Vb3, Vb4, and Vb5 and vacuum regulators Rb1, Rb2, Rb3, Rb4, and Rb5 are attached to the vacuum lines Lb1, Lb2, Lb3, Lb4, and Lb5, respectively. The vacuum valves Vb1, Vb2, Vb3, Vb4, and Vb5 are actuator driven valves, such as solenoid valves, electric valves, or air-operated valves. In one embodiment, vacuum valves Vb1 to Vb5 may be manually operable.

When the vacuum valves Vb1 to Vb5 are opened, the compressed gas in the pressure chambers 25A to 25E are independently discharged from the pressure chambers 25A to 25E through the gas delivery lines F1 to F5 and the vacuum lines Lb1 to Lb5, and negative pressures are formed in the pressure chambers 25A to 25E. The vacuum regulators Rb1 to Rb5 are configured to regulate vacuum pressures in the pressure chambers 25A to 25E.

The vacuum valves Vb1 to Vb5 and the vacuum regulators Rb1 to Rb5 are coupled to the operation controller 9. Operations of the vacuum valves Vb1 to Vb5 and the vacuum regulators Rb1 to Rb5 are controlled by the operation controller 9. When the polishing head 1 holds the wafer W, the vacuum valves Vb1, Vb2, and Vb3 are opened to form vacuum in the pressure chambers 25A, 25B, and 25C while the contact portion 35 of the elastic membrane 34 is in contact with the wafer W. Portions of the contact portion 35 forming these pressure chambers 25A, 25B, and 25C are recessed upward, so that the polishing head 1 can attract the wafer W via a suction cup effect of the elastic membrane 34. When the compressed gas is supplied to the pressure chambers 25A, 25B, and 25C to cancel the suction cup effect, the polishing head 1 can release the wafer W.

The gas delivery lines F1, F2, F3, F4, and F5 are further coupled to vent lines Lc1, Lc2, Lc3, Lc4, and Lc5, respectively, at locations upstream of the rotary joint 40. Vent valves Vc1, Vc2, Vc3, Vc4, and Vc5 are attached to the vent lines Lc1, Lc2, Lc3, Lc4, and Lc5, respectively. The vent valves Vc1, Vc2, Vc3, Vc4, and Vc5 are actuator-driven valves, such as solenoid valves, electric valves, or air-operated valves. In one embodiment, the vent valves Vc1 to Vc5 may be manually operable. When the vent valves Vc1 to Vc5 are opened, the pressure chambers 25A to 25E independently communicate with the atmosphere. The vent valves Vc1 to Vc5 are coupled to the operation controller 9. Operations of the vent valves Vc1 to Vc5 are controlled by the operation controller 9. In one embodiment, the vent lines Lc1 to Lc5 and the vent valves Vc1 to Vc5 may not be provided.

In this embodiment, the gas supply valves Va1 to Va5 are attached to the gas supply lines La1 to La5, respectively, communicating with the pressure chambers 25A to 25E via the gas delivery lines F1 to F5. The vacuum valves Vb1 to Vb5 are attached to the vacuum lines Lb1 to Lb5 respectively, communicating with the pressure chambers 25A to 25E via the gas delivery lines F1 to F5. The vent valves Vc1 to Vc5 are attached to the vent lines Lc1 to Lc5, respectively, communicating with the pressure chambers 25A to 25E via the gas delivery lines F1 to F5. In one embodiment, instead of the gas supply valves Va1 to Va5, the vacuum valves Vb1 to Vb5, and the vent valves Vc1 to Vc5, three-way valves may be attached to the gas delivery lines F1 to F5, respectively. In this case, lines communicating with the pressure chambers 25A to 25E via the gas delivery lines F1 to F5 may be switched among the gas supply lines La1 to La5, the vacuum lines Lb1 to Lb5, and the vent lines Lc1 to Lc5 by operating the three-way valves.

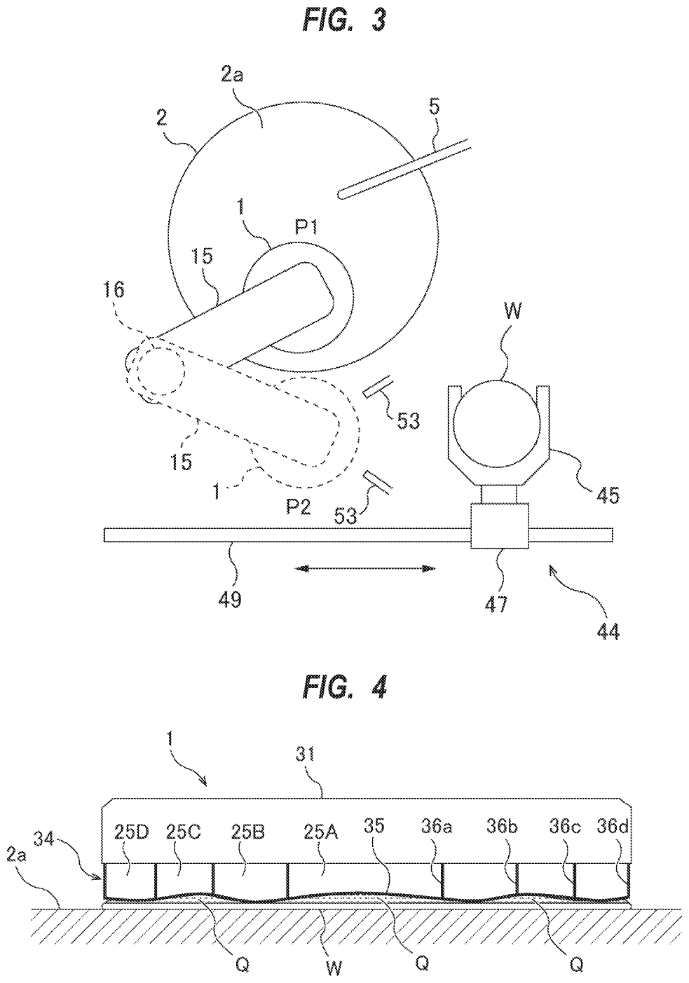

FIG. 3 is a plan view of a transfer device 44 configured to transfer the wafer W to the polishing head 1 shown in FIG. 1. As shown in FIG. 3, the wafer W is transferred to the polishing head 1 by the transfer device 44. The polishing head 1 is movable between a polishing position P1 indicated by a solid line in FIG. 3 and a transfer position P2 indicated by a dotted line. More specifically, the head arm 15 rotates about the support shaft 16, so that the polishing head 1 can move between the polishing position P1 and the transfer position P2. The polishing position P1 is located above the polishing surface 2a of the polishing pad 2, and the transfer position P2 is located outwardly of the polishing surface 2a.

The transfer device 44 includes a transfer stage 45 on which the wafer W is placed, an elevating device 47 configured to vertically move the transfer stage 45, and a horizontally-moving device 49 configured to horizontally move the transfer stage 45 and the elevating device 47 together. The wafer W to be polished is placed on the transfer stage 45, and is moved together with the transfer stage 45 to the transfer position P2 by the horizontally-moving device 49. When the polishing head 1 is placed in the transfer position P2, the elevating device 47 raises the transfer stage 45. The polishing head 1 holds the wafer W on the transfer stage 45, and moves to the polishing position P1 together with the wafer W.

The polishing-liquid supply nozzle 5 supplies the polishing liquid onto the polishing surface 2a of the rotating polishing pad 2, while the polishing head 1 presses the wafer W against the polishing surface 2a of the polishing pad 2 while rotating the wafer W to bring the wafer W into sliding contact with the polishing surface 2a. A lower surface of the wafer W is polished by the chemical action of the polishing liquid and the mechanical action(s) of the abrasive grains contained in the polishing liquid and/or the polishing pad.

After the polishing of the wafer W, the polishing head 1 moves to the transfer position P2 together with the wafer W. The polishing head 1 then transfers the polished wafer W to the transfer stage 45. The transfer stage 45 moves the wafer W to a next process. Cleaning nozzles 53 configured to supply a liquid (e.g., a rinsing liquid, such as pure water) to the polishing head 1 to clean the polishing head 1 are disposed at the transfer position P2. The cleaning nozzles 53 are oriented toward the polishing head 1. The polishing head 1 which has released the wafer W is cleaned with the liquid supplied from the cleaning nozzles 53.

During the cleaning of the polishing head 1, a next wafer to be polished is moved to the transfer position P2 below the polishing head 1 by the transfer stage 45. When the cleaning of the polishing head 1 is terminated, the elevating device 47 raises the transfer stage 45 on which the next wafer has been placed. The cleaned polishing head 1 then holds the next wafer, and moves to the polishing position P1. In this manner, multiple wafers are continuously polished.

However, during the cleaning of the polishing head 1, since the next wafer to be polished is moved to the transfer position P2 below the polishing head 1, the liquid may fall on the upper surface of the wafer in the transfer position P2. The liquid present on the upper surface of the wafer may prevent the polishing head 1 from applying appropriate force to the wafer, as described with reference to FIG. 14. One solution is to move the next wafer to the transfer position P2 after the cleaning of the polishing head 1 terminated. However, such an operation may lower throughput of the polishing apparatus.

Furthermore, when the polishing head 1 attracts the wafer via the suction cup effect of the elastic membrane 34 to hold the next wafer, gas, such as air, may be present between the upper surface of the wafer and the elastic membrane 34 of the polishing head 1. The gas present on the upper surface of the wafer may also prevent the polishing head 1 from applying appropriate force to the wafer, as described with reference to FIG. 14.

Thus, in this embodiment, the fluid is forced to flow out from the upper surface of the wafer as follows. FIG. 4 is a schematic diagram illustrating fluid Q present on the upper surface of the wafer W. In FIG. 4, depiction of the detailed configurations of the polishing head 1 is omitted. The polishing head 1 holding the wafer W to be polished is touched down on the polishing surface 2a of the polishing pad 2 by the vertically moving mechanism 18. When the polishing head 1 is touched down on the polishing surface 2a, the polishing head 1 releases the negative pressures formed in the pressure chambers 25A, 25B, and 25C for attracting the wafer W. FIG. 4 illustrates a state in which the negative pressures formed in the pressure chambers 25A, 25B, and 25C of the polishing head 1 are removed, and the fluid Q is present on the upper surface of the wafer W, i.e., between the wafer W and the elastic membrane 34.

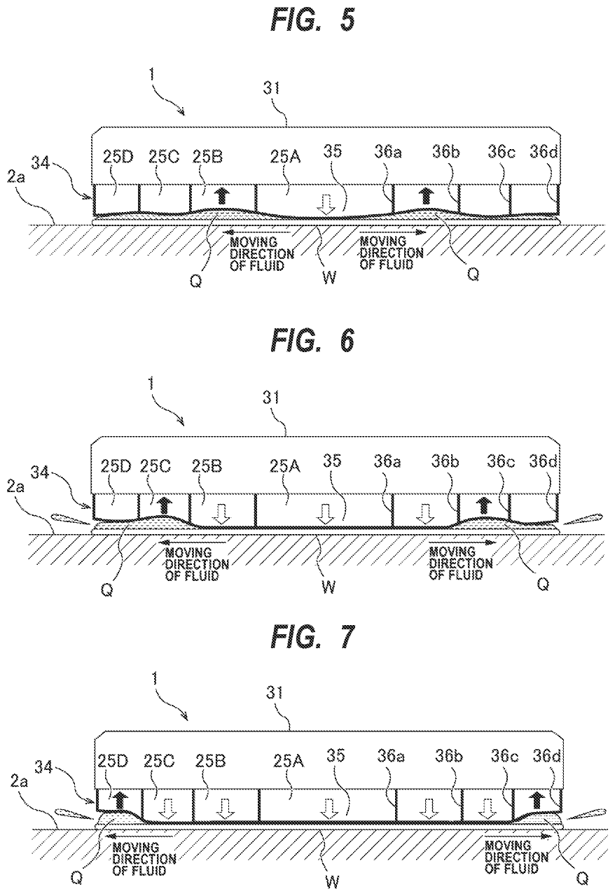

In this embodiment, before polishing of the wafer W, the pressures in the plurality of pressure chambers 25A to 25D are sequentially changed so as to force the fluid Q on the upper surface of the wafer W to move outward, so that the fluid Q is caused to flow out from the upper surface of the wafer W. FIGS. 5 to 8 are schematic diagrams illustrating the elastic membrane 34 of the polishing head 1 when moving the fluid Q present on the upper surface of the wafer W outward to cause the fluid Q to flow out from the upper surface of the wafer W. FIG. 9 is a graph showing a relationship between pressure in the plurality of pressure chambers 25A to 25D and time in this embodiment. In FIG. 9, a solid line indicates pressure that changes over time in the pressure chamber 25A, a thick line indicates pressure that changes over time in the pressure chamber 25B, a dashed line indicates pressure that changes over time in the pressure chamber 25C, and a dash-dot-dash line indicates pressure that changes over time in the pressure chamber 25D.

First, as shown in FIG. 5, a positive pressure is formed in the pressure chamber 25A located in the center of the polishing head 1, and a negative pressure is formed in the pressure chamber 25B located outwardly of the pressure chamber 25A. The pressure chamber 25B is next to the pressure chamber 25A. Forming of the positive pressure in the pressure chamber 25A and forming of the negative pressure in the pressure chamber 25B are performed during a period of time T1 shown in FIG. 9. As shown in FIG. 9, a timing to start forming the positive pressure in the pressure chamber 25A is the same as a timing to start forming the negative pressure in the pressure chamber 25B. During the period of time T1, the pressure in the pressure chamber 25A is increased to a positive-pressure set value PS1, and then the pressure in the pressure chamber 25A is maintained at the positive-pressure set value PS1. During the period of time T1, the pressure in the pressure chamber 25B is lowered to a negative-pressure set value NS1, and the negative pressure in the pressure chamber 25B is then released.

More specifically, during the period of time T1, the operation controller 9 instructs the gas supply valve Va1 (see FIG. 2) to open to establish a fluid communication between the gas supply line La1 and the pressure chamber 25A via the gas delivery line F1. The operation controller 9 instructs the pressure regulator Ra1 (see FIG. 2) to supply the compressed gas into the pressure chamber 25A to increase the pressure in the pressure chamber 25A to the positive-pressure set value PS1. Thereafter, the pressure in the pressure chamber 25A is maintained at the positive-pressure set value PS1. During the period of time T1, the operation controller 9 instructs the vacuum valve Vb2 (see FIG. 2) to open to establish a fluid communication between the vacuum line Lb2 and the pressure chamber 25B via the gas delivery line F2. The operation controller 9 instructs the vacuum regulator Rb2 (see FIG. 2) to reduce the pressure in the pressure chamber 25B to the negative-pressure set value NS1. Thereafter, the operation controller 9 instructs the vacuum valve Vb2 to close. Further, the operation controller 9 instructs the gas supply valve Va2 (see FIG. 2) to open to establish a fluid communication between the gas supply line La2 and the pressure chamber 25B via the gas delivery line F2. The operation controller 9 instructs the pressure regulator Ra2 (see FIG. 2) to supply the compressed gas into the pressure chamber 25B to increase the pressure in the pressure chamber 25B to the atmospheric pressure to thereby release (remove) the negative pressure in the pressure chamber 25B.

As shown in FIG. 5, a central portion of the elastic membrane 34 that forms the pressure chamber 25A is brought into contact with the central portion of the upper surface of the wafer W by forming the positive pressure in the pressure chamber 25A. A portion of the elastic membrane 34 that forms the pressure chamber 25B is lifted upward by the negative pressure formed in the pressure chamber 25B, so that a gap is formed between the upper surface of the wafer W and the pressure chamber 25B. In particular, the inner wall portion 36a located between the pressure chambers 25A and 25B is lifted upward as the negative pressure is formed in the pressure chamber 25B, so that the fluid Q present between the upper surface of the wafer W and the pressure chamber 25A can flow outward. In this manner, during the period of time T1, the positive pressure is formed in the pressure chamber 25A and the negative pressure is formed in the pressure chamber 25B, so that the central portion of the elastic membrane 34 pushes the fluid Q present between the upper surface of the wafer W and the pressure chamber 25A outward to move the fluid Q to the gap between the upper surface of the wafer W and the pressure chamber 25B. Since the positive pressure in the pressure chamber 25A is maintained, the fluid Q that has moved outward remains between the upper surface of the wafer W and the pressure chamber 25B without returning toward the pressure chamber 25A. The fluid Q may further move outward, and may flow out from the upper surface of the wafer W.

Next, as shown in FIG. 6, a positive pressure is formed in the pressure chamber 25B of the polishing head 1 and a negative pressure is formed in the pressure chamber 25C located outwardly of the pressure chamber 25B, while the positive pressure in the pressure chamber 25A is maintained. The pressure chamber 25C is next to the pressure chamber 25B. Forming of the positive pressure in the pressure chamber 25B and forming of the negative pressure in the pressure chamber 25C are performed during a period of time T2 shown in FIG. 9. As shown in FIG. 9, a timing to start forming the positive pressure in the pressure chamber 25B is the same as a timing to start forming the negative pressure in pressure chamber 25C. During the period of time T2, the pressure in the pressure chamber 25B is increased to a positive-pressure set value PS2, and then the pressure in the pressure chamber 25B is maintained at the positive-pressure set value PS2. During the period of time T2, the pressure in the pressure chamber 25C is lowered to a negative-pressure set value NS2, and then the negative pressure in the pressure chamber 25C is released.

More specifically, during the period of time T2, the operation controller 9 instructs the pressure regulator Ra2 to supply the compressed gas into the pressure chamber 25B to increase the pressure in the pressure chamber 25B to the positive-pressure set value PS2. Thereafter, the pressure in the pressure chamber 25B is maintained at the positive-pressure set value PS2. During the period of time T2, the operation controller 9 instructs the vacuum valve Vb3 (see FIG. 2) to open to establish a fluid communication between the vacuum line Lb3 and the pressure chamber 25C via the gas delivery line F3. The operation controller 9 then instructs the vacuum regulator Rb3 (see FIG. 2) to reduce the pressure in the pressure chamber 25C to the negative-pressure set value NS2. Thereafter, the operation controller 9 instructs the vacuum valve Vb3 to close. Further, the operation controller 9 instructs the gas supply valve Va3 (see FIG. 2) to open to establish a fluid communication between the gas supply line La3 and the pressure chamber 25C via the gas delivery line F3. The operation controller 9 instructs the pressure regulator Ra3 (see FIG. 2) to supply the compressed gas into the pressure chamber 25C to increase the pressure in the pressure chamber 25C to the atmospheric pressure to thereby release (remove) the negative pressure in the pressure chamber 25C.

As shown in FIG. 6, the portion of the elastic membrane 34 that forms the pressure chamber 25B is brought into contact with the upper surface of the wafer W by forming the positive pressure in the pressure chamber 25B. A portion of the elastic membrane 34 that forms the pressure chamber 25C is lifted upward by the negative pressure formed in the pressure chamber 25C, so that a gap is formed between the upper surface of the wafer W and the pressure chamber 25C. In particular, the inner wall portion 36b located between the pressure chambers 25B and 25C is lifted upward as the negative pressure is formed in the pressure chamber 25C, so that the fluid Q present between the upper surface of the wafer W and the pressure chamber 25B can flow outward. In this manner, during the period of time T2, the positive pressure is formed in the pressure chamber 25B and the negative pressure is formed in the pressure chamber 25C, so that the portion of the elastic membrane 34 that forms the pressure chamber 25B pushes the fluid Q present between the upper surface of the wafer W and the pressure chamber 25B outward to move the fluid Q to the gap between the upper surface of the wafer W and the pressure chamber 25C. Since the positive pressure in the pressure chamber 25B is maintained, the fluid Q that has moved outward remains between the upper surface of the wafer W and the pressure chamber 25C without returning toward the pressure chamber 25B. The fluid Q may further move outward, and may flow out from the upper surface of the wafer W.

Next, as shown in FIG. 7, a positive pressure is formed in the pressure chamber 25C of the polishing head 1 and a negative pressure is formed in the pressure chamber 25D located outwardly of the pressure chamber 25C, while the positive pressures in the pressure chambers 25A and 25B are maintained. The pressure chamber 25D is next to the pressure chamber 25C. Forming of the positive pressure in the pressure chamber 25C and forming of the negative pressure in the pressure chamber 25D are performed during a period of time T3 shown in FIG. 9. As shown in FIG. 9, a timing to start forming the positive pressure in the pressure chamber 25C is the same as a timing to start forming the negative pressure in the pressure chamber 25D. During the period of time T3, the pressure in the pressure chamber 25C is increased to a positive-pressure set value PS3, and then the pressure in the pressure chamber 25C is maintained at the positive-pressure set value PS3. During the period of time T3, the pressure in the pressure chamber 25D is lowered to a negative-pressure set value NS3, and then the negative pressure in the pressure chamber 25D is released.

More specifically, during the period of time T3, the operation controller 9 instructs the pressure regulator Ra3 to supply the compressed gas into the pressure chamber 25C to increase the pressure in the pressure chamber 25C to the positive-pressure set value PS3. Thereafter, the pressure in the pressure chamber 25C is maintained at the positive-pressure set value PS3. During the period of time T3, the operation controller 9 instructs the vacuum valve Vb4 (see FIG. 2) to open to establish a fluid communication between the vacuum line Lb4 and the pressure chamber 25D via the gas delivery line F4. The operation controller 9 instructs the vacuum regulator Rb4 (see FIG. 2) to lower the pressure in the pressure chamber 25D to the negative-pressure set value NS3. Thereafter, the operation controller 9 instructs the vacuum valve Vb4 to close. Further, the operation controller 9 instructs the gas supply valve Va4 (see FIG. 2) to open to establish a fluid communication between the gas supply line La4 and the pressure chamber 25D via the gas delivery line F4. The operation controller 9 instructs the pressure regulator Ra4 (see FIG. 2) to supply the compressed gas into the pressure chamber 25D to increase the pressure in the pressure chamber 25D to the atmospheric pressure to thereby release (remove) the negative pressure in the pressure chamber 25D.

As shown in FIG. 7, the portion of the elastic membrane 34 that forms the pressure chamber 25C is brought into contact with the upper surface of the wafer W by forming the positive pressure in the pressure chamber 25C. A portion of the elastic membrane 34 that forms the pressure chamber 25D is lifted upward by the negative pressure formed in the pressure chamber 25D, so that a gap is formed between the upper surface of the wafer W and the pressure chamber 25D. In particular, the inner wall portion 36c located between the pressure chambers 25C and 25D is lifted upward as the negative pressure is formed in the pressure chamber 25D, so that the fluid Q present between the upper surface of the wafer W and the pressure chamber 25C can flow outward. In this manner, during the period of time T3, the positive pressure is formed in the pressure chamber 25C and the negative pressure is formed in the pressure chamber 25D, so that the portion of the elastic membrane 34 that forms the pressure chamber 25C pushes the fluid Q present between the upper surface of the wafer W and the pressure chamber 25C outward to move the fluid Q to the gap between the upper surface of the wafer W and the pressure chamber 25D. Since the positive pressure in the pressure chamber 25C is maintained, the fluid Q that has moved outward remains between the upper surface of the wafer W and the pressure chamber 25D without returning toward the pressure chamber 25C. The fluid Q may further move outward, and may flow out from the upper surface of the wafer W.

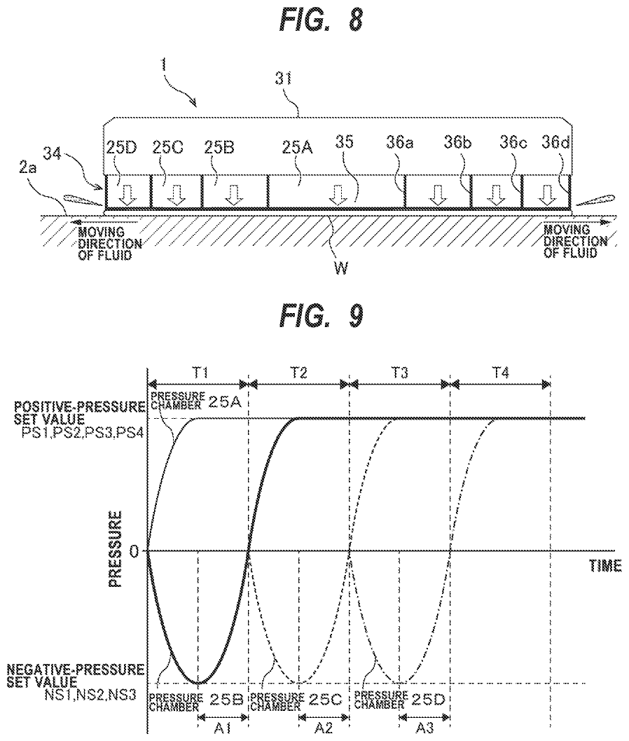

Next, as shown in FIG. 8, a positive pressure is formed in the pressure chamber 25D while the positive pressures in the pressure chambers 25A, 25B, and 25C of the polishing head 1 are maintained. Forming of the positive pressure in the pressure chamber 25D is performed during a period of time T4 shown in FIG. 9. As shown in FIG. 9, during the period of time T4, the pressure in the pressure chamber 25D is increased to a positive-pressure set value PS4, and then the pressure in the pressure chamber 25D is maintained at the positive-pressure set value PS4. More specifically, during the period of time T4, the operation controller 9 instructs the pressure regulator Ra4 to supply the compressed gas into the pressure chamber 25D to increase the pressure in the pressure chamber 25D to the positive-pressure set value PS4. Thereafter, the pressure of the pressure chamber 25D is maintained at the positive-pressure set value PS4.

As shown in FIG. 8, a portion of the elastic membrane 34 that forms the pressure chamber 25D is brought into contact with the upper surface of the wafer W by forming the positive pressure in the pressure chamber 25D which is the outermost pressure chamber. Therefore, during the period of time T4, the portion of the elastic membrane 34 that forms the pressure chamber 25D pushes the fluid Q present between the upper surface of the wafer W and the pressure chamber 25D outward to cause the fluid Q to flow out from the upper surface of the wafer W.

In this embodiment, the fluid Q present on the upper surface of the wafer W can be moved outward by forming the positive pressure in the inner pressure chamber 25A of the adjacent pressure chambers 25A and 25B and forming the negative pressure in the outer pressure chamber 25B. The fluid Q present on the upper surface of the wafer W is further moved outward by sequentially performing this operation in the adjacent pressure chambers 25B and 25C which are located more outwardly than the pressure chambers 25A and 25B, and in the adjacent pressure chambers 25C and 25D which are located more outwardly than the pressure chambers 25B and 25C. Furthermore, the fluid can be caused to flow out from the upper surface of the wafer W by forming the positive pressure in the outermost pressure chamber 25D.

According to this embodiment, the polishing head 1 can hold the wafer W with no fluid Q substantially present between the elastic membrane 34 and the upper surface of the wafer W. Thereafter, the elastic membrane 34 of the polishing head 1 presses the lower surface of the wafer W against the polishing surface 2a while the pressures in the pressure chambers 25A to 25D are controlled according to polishing conditions for the wafer W, so that the lower surface of the wafer W is polished. The elastic membrane 34 presses the lower surface of the wafer W against the polishing surface 2a with no fluid Q substantially present the elastic membrane 34 and the upper surface of the wafer W, so that the polishing head 1 can apply an intended force to the wafer W. As a result, the polishing head 1 can achieve a desired film-thickness profile of the wafer W. A state of no fluid Q substantially present between the elastic membrane 34 and the upper surface of the wafer W includes not only a state of no fluid Q present at all, but also a state in which the fluid Q has flowed out from the wafer W to such a degree that the pressure chambers 25A to 25D of the polishing head 1 can apply appropriate forces to the corresponding plurality of regions of the wafer W.

In this embodiment, the positive-pressure set values PS1, PS2, PS3, and PS4 are the same, while the positive-pressure set values PS1, PS2, PS3, and PS4 may be different positive pressure values. In this embodiment, the negative-pressure set values NS1, NS2, and NS3 are the same, while the negative-pressure set values NS1, NS2, and NS3 may be different negative pressure values.

In this embodiment, lengths of the periods of time T1 to T4 are the same, while lengths of the periods of time T1, T2, T3, and T4 are not limited to this embodiment as long as the fluid Q present on the upper surface of the wafer W can be moved outward and can flow out from the upper surface of the wafer W. The lengths of the periods of time T1, T2, T3, and T4 may be adjusted based on volumes in the pressure chambers 25A to 25D, flow rates of the compressed gas supplied from the gas supply lines La1 to La4, flow rates of the compressed gas discharged to the vacuum lines Lb1 to Lb4, etc.

In this embodiment, first, the fluid Q present on the upper surface of the wafer W is moved outward by forming the positive pressure in the inner pressure chamber 25A of the adjacent pressure chambers 25A and 25B and forming the negative pressure in the outer pressure chamber 25B of the adjacent pressure chambers 25A and 25B. However, the two adjacent pressure chambers from which this operation is started are not limited to the pressure chambers 25A and 25B. In one embodiment, when no fluid Q is present between the upper surface of the wafer W and the pressure chamber 25A and the fluid Q is present between the upper surface of the wafer W and the pressure chamber 25B, first, the fluid Q present between the upper surface of the wafer W and the pressure chamber 25B may be moved outward by forming a positive pressure in the inner pressure chamber 25B of the adjacent pressure chambers 25B and 25C and forming a negative pressure in the outer pressure chamber 25C of the adjacent pressure chambers 25B and 25C. In this case, the positive pressure is formed in the pressure chambers 25A in advance. The fluid Q present on the upper surface of the wafer W can be further moved outward by sequentially performing this operation in the adjacent pressure chambers 25C and 25D which are located more outwardly than the pressure chambers 25B and 25C. Furthermore, the fluid can be caused to flow out from the upper surface of the wafer W by forming a positive pressure in the outermost pressure chamber 25D. In this manner, the two adjacent pressure chambers from which the operation is started may be appropriately changed according to the position of the fluid Q present on the upper surface of the wafer W.

In one embodiment, the elastic membrane 34 may form three pressure chambers 25A, 25B, and 25C, and the outermost pressure chamber may be the pressure chamber 25C. In this embodiment, the fluid Q present on the upper surface of the wafer W may be moved outward by forming a positive pressure in the inner pressure chamber 25A of the adjacent pressure chambers 25A and 25B and forming a negative pressure in the outer pressure chamber 25B of the adjacent pressure chambers 25A and 25B. Thereafter, the fluid Q present on the upper surface of the wafer W may be further moved outward by forming a positive pressure the inner pressure chamber 25B of the adjacent pressure chambers 25B and 25C which are located more outwardly than the pressure chambers 25A and 25B, and forming a negative pressure in the outer pressure chamber 25C of the adjacent pressure chambers 25B and 25C. Furthermore, the fluid Q may be caused to flow out from the upper surface of the wafer W by forming a positive pressure in the outermost pressure chamber 25C.

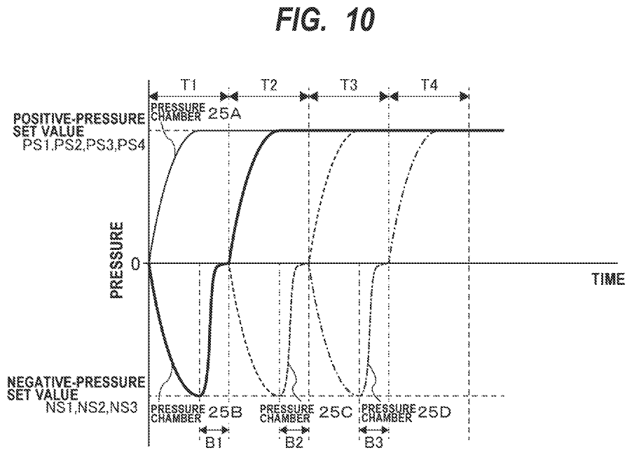

FIG. 10 is a graph showing a relationship between pressure in the plurality of pressure chambers 25A to 25D and time according to another embodiment of a method of causing the fluid Q to flow out from the upper surface of the wafer W. Details of the present embodiment, which will not be particularly described, are the same as those of the above-described embodiments, and duplicated descriptions will be omitted. In this embodiment, the pressures in the pressure chambers 25B, 25C, and 25D are lowered to negative-pressure set values NS1, NS2, and NS3, respectively, and then the pressure chambers 25B, 25C, and 25D are communicated with the atmosphere, so that the negative pressures in the pressure chambers 25B, 25C, and 25D are released (removed).

During a period of time T1, a positive pressure is formed in the pressure chamber 25A, the pressure in the pressure chamber 25B is lowered to a negative-pressure set value NS1, and the pressure chamber 25B is then communicated with the atmosphere. The operation of forming the positive pressure in the pressure chamber 25A is the same as that of the embodiment described with reference to FIGS. 5 to 9. During the period of time T1, the operation controller 9 instructs the vacuum valve Vb2 to open to establish a fluid communication between the vacuum line Lb2 and the pressure chamber 25B via the gas delivery line F2. The operation controller 9 instructs the vacuum regulator Rb2 to lower the pressure in the pressure chamber 25B to the negative-pressure set value NS1. The operation controller 9 then instructs the vacuum valve Vb2 to close. Further, the operation controller 9 instructs the vent valve Vc2 (see FIG. 2) to open to establish a fluid communication between the pressure chamber 25B and the atmosphere.

During a period of time T2, a positive pressure is formed in the pressure chamber 25B, the pressure in the pressure chamber 25C is lowered to a negative-pressure set value NS2, and then the pressure chamber 25C is communicated with the atmosphere. The operation of forming the positive pressure in the pressure chamber 25B is the same as that of the embodiment described with reference to FIGS. 5 to 9. During the period of time T2, the operation controller 9 instructs the vacuum valve Vb3 to open to establish a fluid communication between the vacuum line Lb3 and the pressure chamber 25C via the gas delivery line F3. The operation controller 9 then instructs the vacuum regulator Rb3 to lower the pressure in the pressure chamber 25C to the negative-pressure set value NS2. The operation controller 9 then instructs the vacuum valve Vb3 to close. Further, the operation controller 9 instructs the vent valve Vc3 (see FIG. 2) to open to establish a fluid communication between the pressure chamber 25C and the atmosphere.

During a period of time T3, a positive pressure is formed in the pressure chamber 25C, the pressure in the pressure chamber 25D is lowered to a negative-pressure set value NS3, and then the pressure chamber 25D is communicated with the atmosphere. The operation of forming the positive pressure in the pressure chamber 25C is the same as that of the embodiment described with reference to FIGS. 5 to 9. During the period of time T3, the operation controller 9 instructs the vacuum valve Vb4 to open to establish a fluid communication between the vacuum line Lb4 and the pressure chamber 25D via the gas delivery line F4. The operation controller 9 then instructs the vacuum regulator Rb4 to lower the pressure in the pressure chamber 25D to the negative-pressure set value NS3. Thereafter, the operation controller 9 instructs the vacuum valve Vb4 to close. Further, the operation controller 9 instructs the vent valve Vc4 (see FIG. 2) to open to establish a fluid communication between the pressure chamber 25D and the atmosphere.

A positive pressure is formed in the pressure chamber 25D during a period of time T4. The operation of forming the positive pressure in the pressure chamber 25D is the same as that of the embodiment described with reference to FIGS. 5 to 9.

Releasing (removing) of the negative pressure in the pressure chambers 25B, 25C, and 25D caused by the fluid communication between the pressure chambers 25B, 25C, 25D and the atmosphere can be achieved in a shorter time than releasing of the negative pressure in the pressure chambers 25B, 25C, and 25D caused by the supply of the compressed gas into the pressure chambers 25B, 25C, and 25D. In the above-described embodiment shown in FIG. 9, when the negative pressure in the pressure chamber 25B is released by the supply of the compressed gas into the pressure chamber 25B, this operation takes a period of time A1. In contrast, in the present embodiment shown in FIG. 10, when the negative pressure in the pressure chamber 25B is released by establishing the fluid communication between the pressure chamber 25B and the atmosphere, this operation can be performed in a period of time B1 which is shorter than the period of time A1.

As well as in the pressure chamber 25C, a period of time B2 (see FIG. 10) taken to establish the fluid communication between the pressure chamber 25C and the atmosphere to release the negative pressure in the pressure chamber 25C is shorter than the period of time A2 (see FIG. 9) taken to supply the compressed gas into the pressure chamber 25C to release the negative pressure in the pressure chamber 25C. As well as in the pressure chamber 25D, a period of time B3 (see FIG. 10) taken to establish the fluid communication between the pressure chamber 25D and the atmosphere to release the negative pressure in the pressure chamber 25D is shorter than the period of time A3 (see FIG. 9) taken to supply the compressed gas into the pressure chamber 25D to release the negative pressure in the pressure chamber 25D.

According to the present embodiment, since the periods of time B1, B2, and B3 taken to release the negative pressure in the pressure chambers 25B, 25C, and 25D are shorter than the periods of time A1, A2, and A3, a total time taken for the fluid Q to flow out from the upper surface of the wafer W can be reduced.

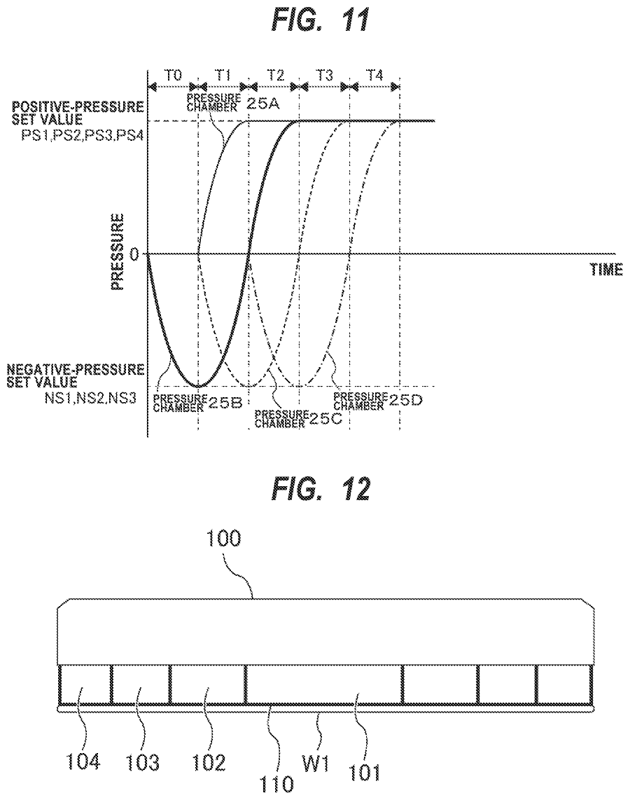

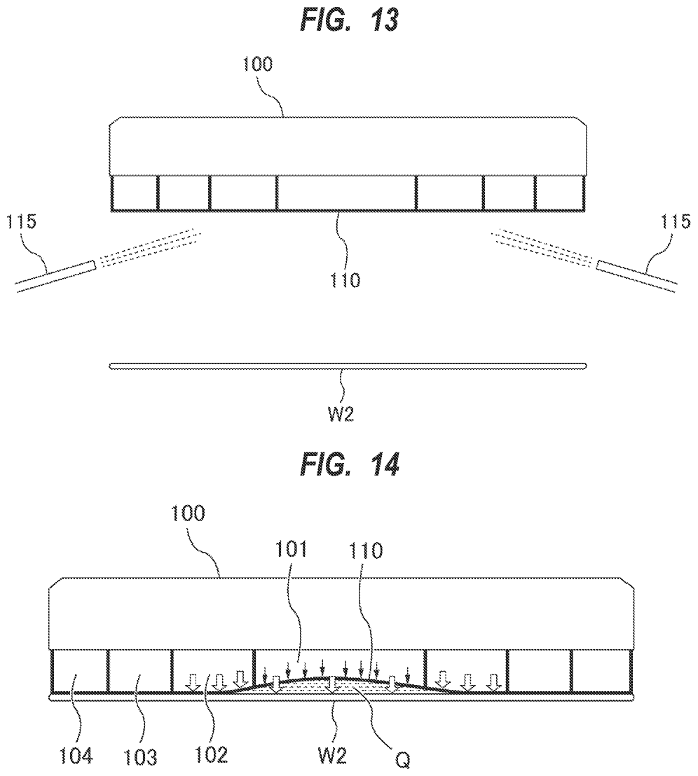

FIG. 11 is a graph showing a relationship between pressure in the plurality of pressure chambers 25A to 25D and time according to still another embodiment of the method of causing the fluid Q to flow out from the upper surface of the wafer W. Details of this embodiment, which will not be particularly described, are the same as those of the embodiments described with reference to FIGS. 5 to 9, and duplicated descriptions will be omitted. In this embodiment, a timing to start forming a negative pressure in an outer pressure chamber of adjacent pressure chambers is prior to a timing to start forming a positive pressure in an inner pressure chamber of the adjacent pressure chambers.

As shown in FIG. 11, in the present embodiment, a timing to start forming a negative pressure in the pressure chamber 25B is prior to a timing to start forming a positive pressure in the pressure chamber 25A. Specifically, during a period of time TO, the pressure in the pressure chamber 25B is lowered to a negative-pressure set value NS1. Thereafter, during a period of time T1, the negative pressure in the pressure chamber 25B is released, and the pressure in the pressure chamber 25A is increased to a positive-pressure set value PS1. Thereafter, the pressure in the pressure chamber 25A is maintained at the positive-pressure set value PS1. Therefore, during the period of time T1, the positive pressure is formed in the pressure chamber 25A located in the center of the polishing head 1, and the negative pressure is formed in the pressure chamber 25B located outwardly of the pressure chamber 25A.

More specifically, during the period of time TO, the operation controller 9 instructs the vacuum valve Vb2 to open to establish a fluid communication between the vacuum line Lb2 and the pressure chamber 25B via the gas delivery line F2. The operation controller 9 instructs the vacuum regulator Rb2 to lower the pressure in the pressure chamber 25B to the negative-pressure set value NS1. Thereafter, during the period of time T1, the operation controller 9 instructs the vacuum valve Vb2 to close. Further, the operation controller 9 instructs the gas supply valve Va2 to open to establish a fluid communication between the gas supply line La2 and the pressure chamber 25B via the gas delivery line F2. The operation controller 9 instructs the pressure regulator Ra2 to supply the compressed gas into the pressure chamber 25B to increase the pressure in the pressure chamber 25B to the atmospheric pressure to thereby release (remove) the negative pressure in the pressure chamber 25B. During the period of time T1, the operation controller 9 instructs the gas supply valve Va1 to open to establish a fluid communication between the gas supply line La1 and the pressure chamber 25A via the gas delivery line F1. The operation controller 9 instructs the pressure regulator Ra1 to supply the compressed gas into the pressure chamber 25A to increase the pressure in the pressure chamber 25A to the positive-pressure set value PS1. Thereafter, the pressure in the pressure chamber 25A is maintained at the positive-pressure set value PS1.

In this embodiment, the positive pressure is formed in the pressure chamber 25A while the negative pressure in the pressure chamber 25B is released in the period of time T1. Since the pressure in the pressure chamber 25B is still negative while the negative pressure in the pressure chamber 25B is being released, the fluid Q present between the upper surface of the wafer W and the pressure chamber 25A can be pushed outward to the gap between the upper surface of the wafer W and the pressure chamber 25B during the period of time T1 (see FIG. 5).

Furthermore, in the present embodiment, a timing to start forming a negative pressure in the pressure chamber 25C is prior to a timing to start forming a positive pressure in the pressure chamber 25B. Specifically, the pressure in the pressure chamber 25C is lowered to a negative-pressure set value NS2 during the period of time T1. Thereafter, during a period of time T2, the negative pressure in the pressure chamber 25C is released (removed), and the pressure in the pressure chamber 25B is increased to a positive-pressure set value PS2. Thereafter, the pressure in the pressure chamber 25B is maintained at the positive-pressure set value PS2. Therefore, during the period of time T2, the positive pressure is formed in the pressure chamber 25B, and the negative pressure is formed in the pressure chamber 25C located outwardly of the pressure chamber 25B.

More specifically, during the period of time T1, the operation controller 9 instructs the vacuum valve Vb3 to open to establish a fluid communication between the vacuum line Lb3 and the pressure chamber 25C via the gas delivery line F3. The operation controller 9 instructs the vacuum regulator Rb3 to lower the pressure in the pressure chamber 25C to the negative-pressure set value NS2. Thereafter, during the period of time T2, the operation controller 9 instructs the vacuum valve Vb3 to close. Further, the operation controller 9 instructs the gas supply valve Va3 to open to establish a fluid communication between the gas supply line La3 and the pressure chamber 25C via the gas delivery line F3. The operation controller 9 instructs the pressure regulator Ra3 to supply the compressed gas into the pressure chamber 25C to increase the pressure in the pressure chamber 25C to the atmospheric pressure to thereby release (remove) the negative pressure in the pressure chamber 25C. During the period of time T2, the operation controller 9 instructs the gas supply valve Va2 to open to establish a fluid communication between the gas supply line La2 and the pressure chamber 25B via the gas delivery line F2. The operation controller 9 instructs the pressure regulator Ra2 to supply the compressed gas into the pressure chamber 25B to increase the pressure in the pressure chamber 25B to the positive-pressure set value PS2. Thereafter, the pressure in the pressure chamber 25B is maintained at the positive-pressure set value PS2.

In this embodiment, the positive pressure is formed in the pressure chamber 25B while the negative pressure in the pressure chamber 25C is released in the period of time T2. Since the pressure in the pressure chamber 25C is still negative while the negative pressure in the pressure chamber 25C is being released (removed), the fluid Q present between the upper surface of the wafer W and the pressure chamber 25B can be pushed outward to the gap between the upper surface of the wafer W and the pressure chamber 25C during the period of time T2 (see FIG. 6).

Furthermore, in the present embodiment, a timing to start forming a negative pressure in the pressure chamber 25D is prior to a timing to start forming the positive pressure in the pressure chamber 25C. Specifically, the pressure in the pressure chamber 25D is lowered to a negative-pressure set value NS3 during the period of time T2. Thereafter, during a period of time T3, the negative pressure in the pressure chamber 25D is released (removed), and the pressure in the pressure chamber 25C is increased to a positive-pressure set value PS3. Thereafter, the pressure in the pressure chamber 25C is maintained at the positive-pressure set value PS3. Therefore, during the period of time T3, the positive pressure is formed in the pressure chamber 25C, and the negative pressure is formed in the pressure chamber 25D located outwardly of the pressure chamber 25C.

More specifically, during the period of time T2, the operation controller 9 instructs the vacuum valve Vb4 to open to establish a fluid communication between the vacuum line Lb4 and the pressure chamber 25D via the gas delivery line F4. The operation controller 9 instructs the vacuum regulator Rb4 to lower the pressure in the pressure chamber 25D to the negative-pressure set value NS3. Thereafter, during the period of time T3, the operation controller 9 instructs the vacuum valve Vb4 to close. Further, the operation controller 9 instructs the gas supply valve Va4 to open to establish a fluid communication between the gas supply line La4 and the pressure chamber 25D via the gas delivery line F4. The operation controller 9 instructs the pressure regulator Ra4 to supply the compressed gas into the pressure chamber 25D to increase the pressure in the pressure chamber 25D to the atmospheric pressure to thereby release (remove) the negative pressure in the pressure chamber 25D. During the period of time T3, the operation controller 9 instructs the gas supply valve Va3 to open to establish a fluid communication between the gas supply line La3 and the pressure chamber 25C via the gas delivery line F3. The operation controller 9 instructs the pressure regulator Ra3 to supply the compressed gas into the pressure chamber 25C to increase the pressure in the pressure chamber 25C to the positive-pressure set value PS3. Thereafter, the pressure in the pressure chamber 25C is maintained at the positive-pressure set value PS3.

In this embodiment, the positive pressure is formed in the pressure chamber 25C while the negative pressure in the pressure chamber 25D is released in the period of time T3. Since the pressure in the pressure chamber 25D is still negative while the negative pressure in the pressure chamber 25D is being released (removed), the fluid Q present between the upper surface of the wafer W and the pressure chamber 25C can be pushed outward to the gap between the upper surface of the wafer W and the pressure chamber 25D during the period of time T3 (see FIG. 7).

Furthermore, in the present embodiment, the pressure in the pressure chamber 25D is increased to a positive-pressure set value PS4 during a period of time T4. Thereafter, the pressure in the pressure chamber 25D is maintained at the positive-pressure set value PS4. During the period of time T4, the operation controller 9 instructs the gas supply valve Va4 to open to establish a fluid communication between the gas supply line La4 and the pressure chamber 25D via the gas delivery line F4. The operation controller 9 instructs the pressure regulator Ra4 to supply the compressed gas into the pressure chamber 25D to increase the pressure in the pressure chamber 25D to the positive-pressure set value PS4. Thereafter, the pressure in the pressure chamber 25D is maintained at the positive-pressure set value PS4.

In this embodiment, the fluid Q present between the upper surface of the wafer W and the pressure chamber 25D is pushed outward by the positive pressure formed in the pressure chamber 25D in the period of time T4, so that the fluid Q can flow out from the upper surface of the wafer W (see FIG. 8).

According to this embodiment, the total time taken for the fluid Q to flow out from the upper surface of the wafer W can be reduced compared to the total time of the embodiments described with reference to FIGS. 5 to 9, because the timing to start forming the negative pressure in the outer pressure chamber of the adjacent pressure chambers is prior to the timing to start forming the positive pressure in the inner pressure chamber of the adjacent pressure chambers.

In one embodiment, lowering the pressure in the pressure chamber 25B to the negative-pressure set value NS1 in the period of time TO may comprise forming a negative pressure in the pressure chamber 25B in order to attract and hold the wafer W before the polishing head 1 touches down on the polishing surface 2a of the polishing pad 2. In this case, after the polishing head 1 touches down on the polishing surface 2a, formation of the positive pressure in the pressure chamber 25A may be started and release of the negative pressure in the pressure chamber 25B may be started as shown in the period of time T1 in FIG. 11. As a result, the total time taken for the fluid Q to flow out from the upper surface of the wafer W can be further reduced.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A polishing method for a wafer using a polishing head having a plurality of pressure chambers formed by an elastic membrane, comprising:
forming a positive pressure in a first pressure chamber and forming a negative pressure in a second chamber to move fluid present between an upper surface of the wafer and the first pressure chamber outward, the plurality of pressure chambers including the first pressure chamber and the second pressure chamber located outwardly of the first pressure chamber; then
forming a positive pressure in the second chamber and forming a negative pressure in a third pressure chamber to move the fluid present between the upper surface of the wafer and the second pressure chamber outward, the plurality of pressure chambers further including the third pressure chamber located outwardly of the second pressure chamber; then
forming a positive pressure in outermost pressure chamber of the plurality of pressure chambers to move the fluid present between the upper surface of the wafer and the outermost pressure chamber outward to thereby cause the fluid to flow out from the upper surface of the wafer; and then
pressing a lower surface of the wafer against a polishing surface with the elastic membrane to polish the lower surface of the wafer.

2. The polishing method according to claim 1, wherein
a timing to start forming the positive pressure in the first pressure chamber is the same as a timing to start forming the negative pressure in the second pressure chamber, and
a timing to start forming the positive pressure in the second pressure chamber is the same as a timing to start forming the negative pressure in the third pressure chamber.

3. The polishing method according to claim 2, wherein
forming the negative pressure in the second pressure chamber includes lowering a pressure in the second pressure chamber to a negative-pressure set value, and then establishing a fluid communication between the second pressure chamber and the atmosphere, and
forming the negative pressure in the third pressure chamber includes lowering a pressure in the third pressure chamber to a negative-pressure set value, and then establishing a fluid communication between the third pressure chamber and the atmosphere.

4. The polishing method according to claim 1, wherein
a timing to start forming the negative pressure in the second pressure chamber is prior to a timing to start forming the positive pressure in the first pressure chamber, and
a timing to start forming the negative pressure in the third pressure chamber is prior to a timing to start forming the positive pressure in the second pressure chamber.

5. The polishing method according to claim 4, wherein
forming the negative pressure in the second pressure chamber includes lowering a pressure in the second pressure chamber to a negative-pressure set value, and then releasing the negative pressure in the second pressure chamber,
forming the positive pressure in the first pressure chamber is performed during releasing of the negative pressure in the second pressure chamber,
forming the negative pressure in the third pressure chamber includes lowering a pressure in the third pressure chamber to a negative-pressure set value, and then releasing the negative pressure in the third pressure chamber, and
forming the positive pressure in the second pressure chamber is performed during releasing of the negative pressure in the third pressure chamber.

6. The polishing method according to claim 1, wherein the first pressure chamber is located at a central portion of the elastic membrane.

7. The polishing method according to claim 1, wherein
forming the positive pressure in the first pressure chamber includes increasing a pressure in the first pressure chamber to a first positive-pressure set value, and then maintaining the pressure in the first pressure chamber at the first positive-pressure set value, and
forming the positive pressure in the second pressure chamber includes increasing a pressure in the second pressure chamber to a second positive-pressure set value, and then maintaining the pressure in the second pressure chamber at the second positive-pressure set value.

8. A polishing apparatus for polishing a wafer, comprising:
a polishing head having a plurality of pressure chambers formed by an elastic membrane, the polishing head being configured to press the wafer against a polishing surface with the plurality of pressure chambers, the plurality of pressure chambers including a first pressure chamber, a second pressure chamber located outwardly of the first pressure chamber, and a third pressure chamber located outwardly of the second pressure chamber; and
an operation controller configured to control an operation of the polishing apparatus, the operation controller being configured to instruct the polishing apparatus to:
form a positive pressure in the first pressure chamber and form a negative pressure in the second chamber to move fluid present between an upper surface of the wafer and the first pressure chamber outward;
form a positive pressure in the second chamber and form a negative pressure in the third pressure chamber to move the fluid present between the upper surface of the wafer and the second pressure chamber outward;
form a positive pressure in outermost pressure chamber of the plurality of pressure chambers to move the fluid present between the upper surface of the wafer and the outermost pressure chamber outward to thereby cause the fluid to flow out from the upper surface of the wafer; and then
press a lower surface of the wafer against the polishing surface with the elastic membrane to polish the lower surface of the wafer.

9. The polishing apparatus according to claim 8, wherein the operation controller is configured to:
operate the polishing apparatus such that a timing to start forming the positive pressure in the first pressure chamber is the same as a timing to start forming the negative pressure in the second pressure chamber; and
operate the polishing apparatus such that a timing to start forming the positive pressure in the second pressure chamber is the same as a timing to start forming the negative pressure in the third pressure chamber.

10. The polishing apparatus according to claim 9, wherein the operation controller is configured to:
operate the polishing apparatus such that forming the negative pressure in the second pressure chamber includes lowering a pressure in the second pressure chamber to a negative-pressure set value, and then establishing a fluid communication between the second pressure chamber and the atmosphere; and
operate the polishing apparatus such that forming the negative pressure in the third pressure chamber includes lowering a pressure in the third pressure chamber to a negative-pressure set value, and then establishing a fluid communication between the third pressure chamber and the atmosphere.

11. The polishing apparatus according to claim 8, wherein the operation controller is configured to:
operate the polishing apparatus such that a timing to start forming the negative pressure in the second pressure chamber is prior to a timing to start forming the positive pressure in the first pressure chamber; and
operate the polishing apparatus such that a timing to start forming the negative pressure in the third pressure chamber is prior to a timing to start forming the positive pressure in the second pressure chamber.

12. The polishing apparatus according to claim 11, wherein the operation controller is configured to:
operate the polishing apparatus such that forming the negative pressure in the second pressure chamber includes lowering a pressure in the second pressure chamber to a negative-pressure set value, and then releasing the negative pressure in the second pressure chamber, forming the positive pressure in the first pressure chamber being performed during releasing of the negative pressure in the second pressure chamber; and
operate the polishing apparatus such that forming the negative pressure in the third pressure chamber includes lowering a pressure in the third pressure chamber to a negative-pressure set value, and then releasing the negative pressure in the third pressure chamber, forming the positive pressure in the second pressure chamber being performed during releasing of the negative pressure in the third pressure chamber.

13. The polishing apparatus according to claim 8, wherein the first pressure chamber is located at a central portion of the elastic membrane.

14. The polishing apparatus according to claim 8, wherein the operation controller is configured to:
operate the polishing apparatus such that forming the positive pressure in the first pressure chamber includes increasing a pressure in the first pressure chamber to a first positive-pressure set value, and then maintaining the pressure in the first pressure chamber at the first positive-pressure set value; and
operate the polishing apparatus such that forming the positive pressure in the second pressure chamber includes increasing a pressure in the second pressure chamber to a second positive-pressure set value, and then maintaining the pressure in the second pressure chamber at the second positive-pressure set value.
